(19) United States
(12) Patent Application Publication
(10) Pub. No.: US 2017/0162731 A1
(43) Pub. Date: Jun. 8, 2017

(54) PHOTOVOLTAIC MODULE

(71) Applicant: Industrial Technology Research Institute, Hsinchu (TW)

(72) Inventors: Chia-Wen Chang, New Taipei City (TW); Wei-Sheng Lin, Taoyuan City (TW); Sung-Yu Chen, Taichung City (TW); Hsi-Chuan Chen, Hsinchu City (TW)

(21) Appl. No.: 14/983,596

(22) Filed: Dec. 30, 2015

(30) Foreign Application Priority Data
Dec. 7, 2015 (TW) 104140994

(51) Int. Cl. H01L 31/032; H01L 31/0203; H01L 31/0224

(52) U.S. Cl. CPC H01L 31/032; H01L 31/022466; H01L 31/0203

(57) ABSTRACT

A PV module includes a transparent substrate, a first solar cell unit, a crystalline silicon solar cell, and a spacer. The first solar cell unit is between the transparent substrate and the crystalline silicon solar cell, and the first solar cell unit includes a first electrode, a second electrode, and a I-III-VI semiconductor layer between the first electrode and the second electrode. The I-III-VI semiconductor layer includes at least gallium (Ga) and sulfur (S), and the energy gap thereof is more than that of crystalline silicon. Moreover, the crystalline silicon solar cell and the first solar cell unit are separated by the spacer.

### CROSS-REFERENCE TO RELATED APPLICATION

This application claims the priority benefits of Taiwan application serial no. 104140994, filed on Dec. 7, 2015. The entirety of the above-mentioned patent application is hereby incorporated by reference herein and made a part of this specification.

### TECHNICAL FIELD

The disclosure relates to a photovoltaic (PV) module.

### BACKGROUND

The structure of an encapsulation structure of the traditional crystalline silicon solar cell from the surface that the light enters is glass/ethylene vinyl acetate copolymer (EVA)/crystalline silicon cell/EVA/Tedlar sequentially. The top of the crystalline silicon solar cell is made of glass, EVA, or the like, as an encapsulation material for the front side while the underneath of the crystalline silicon solar cell is usually made of EVA encapsulation film, or polyvinyl butyral (PVB), silica gel, and the like, as an encapsulation material of the solar cell.

However, the EVA film will receive the effects of light, heat, oxygen, and the like, with time. Thus, after the EVA film absorbs UV light, color of the material thereof may change from transparent to tawny due to the degradation of the chemical structure. The main disadvantage of the EVA film in usage is yellowing. The transmittance of the incident light is decreased after the EVA film occurs yellowing. In addition, the efficiency of the PV module is decreased with increasing the usage time since the EVA encapsulation film above the solar cell occurs yellowing. Such is the significant problem on lifetime of the solar cell and module currently.

### SUMMARY

One embodiment of the disclosure provides a PV module including a transparent substrate, a first solar cell unit, a crystalline silicon solar cell, and a spacer. The first solar cell unit is located between the transparent substrate and the crystalline silicon solar cell. The first solar cell unit includes a first electrode, a second electrode, and a I-III-VI semiconductor layer located between the first electrode and the second electrode, wherein the I-III-VI semiconductor layer includes at least gallium (Ga) and sulfur (S). The energy gap of the I-III-VI semiconductor layer is more than that of crystalline silicon. Moreover, the spacer is configured to separate the crystalline silicon solar cell and the first solar cell unit.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1 is a schematic cross-sectional view of a PV module in accordance with a first embodiment of the disclosure.

FIG. 2 is a schematic cross-sectional view of a PV module in accordance with a second embodiment of the disclosure.

FIG. 3 is a schematic cross-sectional view of a PV module in accordance with a third embodiment of the disclosure.

FIG. 4 is a schematic cross-sectional view of a PV module in accordance with a fourth embodiment of the disclosure.

FIG. 5 is a schematic cross-sectional view of a PV module in accordance with a fifth embodiment of the disclosure.

FIG. 6 is a schematic cross-sectional view of a PV module in accordance with a sixth embodiment of the disclosure.

### DETAILED DESCRIPTION

The embodiments of the disclosure are described more fully hereinafter with reference to the accompanying drawings, but the disclosure may be embodied in many other different forms. For clarity, in the drawings, the relative sizes and positions of each structure and region could be reduced or enlarged. It should be understood that although “the first”, “the second”, or the like, are utilized to describe different structures and regions, these structures or regions should not be construed as limited to the wording. That is, the first surface, region, or structure discussed below may be called as the second surface, region, or structure, and will not violate the teaching of the embodiments.

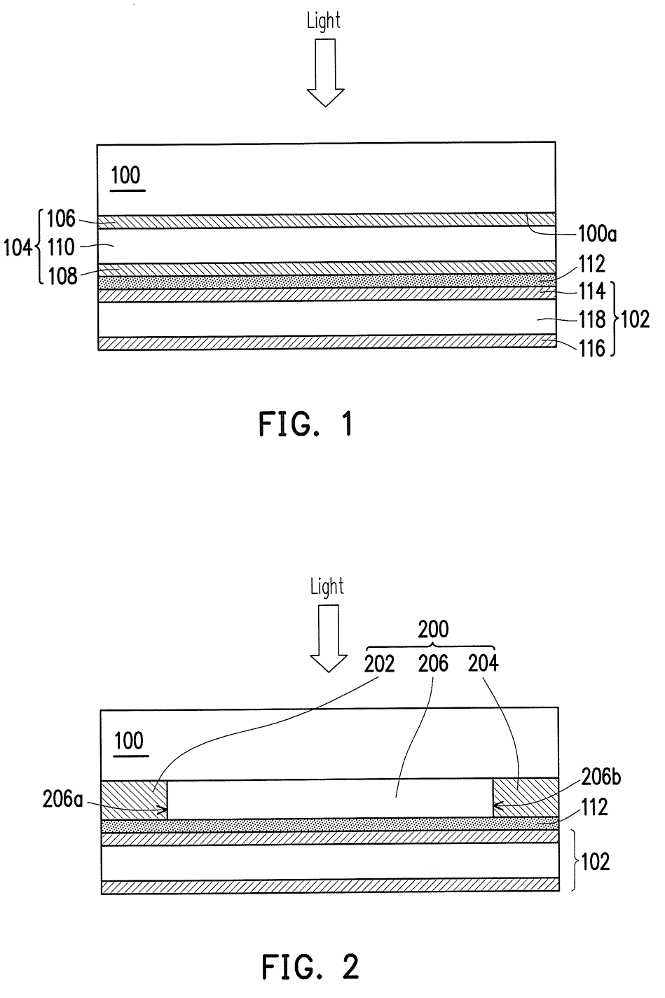

FIG. 1 is a schematic cross-sectional view of a PV module in accordance with a first embodiment of the disclosure.

Referring to FIG. 1, the PV module of the first embodiment includes a transparent substrate 100, a crystalline silicon solar cell 102, and a first solar cell unit 104. The transparent substrate 100 may be glass or plastic, for example, and the crystalline silicon solar cell 102 is located on an opposite surface 100a relative to a light-irradiated surface of the transparent substrate 100. That is, if the light enters from a front side of the transparent substrate 100, the position of the crystalline silicon solar cell 102 is on a backside of the transparent substrate 100. The first solar cell unit 104 is provided between the transparent substrate 100 and the crystalline silicon solar cell 102. The first solar cell unit 104 includes a first electrode 106, a second electrode 108, and a I-III-VI semiconductor layer 110 between the first electrode 106 and the second electrode 108. The first electrode 106 and the second electrode 108 are respectively located on both surfaces of the I-III-VI semiconductor layer 110 in a thickness direction. The crystalline silicon solar cell 102 and the first solar cell unit 104 are separated by a space 112 covering the crystalline silicon solar cell 102 completely. The I-III-VI semiconductor layer 110 may be formed on one side surface 100a of the transparent substrate 100 by vacuum method (e.g. sputtering or evaporation) or non-vacuum method (e.g. printing).

In the present embodiment, the first solar cell unit 104 may absorb the light with wavelength of 800 nm or less, such as the light with wavelength of 500 nm or less. Therefore, it is possible to use the I-III-VI semiconductor layer 110 at least including gallium (Ga) and sulfur (S). For example, the I-III-VI semiconductor layer 110 includes but not limits to copper (indium, gallium) disulfide (Cu(In,Ga)S₂), copper gallium disulfide (CuGaS₂), (copper, silver) (indium, gallium) disulfide (Cu,Ag)(In,Ga)S₂), (copper, silver) gallium disulfide (Cu,Ag)GaS₂), copper (indium, gallium) oxy-sulfide (Cu(In,Ga)(O,S)₂), copper gallium oxy-sulfide (CuGa(O,S)₂), (copper, silver) (indium, gallium) oxy-sulfide (Cu,Ag)(In,Ga)(O,S)₂), or copper (indium, gallium) (selenium, sulfide) (Cu(In,Ga)(Se,S)₂). A band gap of the I-III-VI semiconductor material is about 1.5 eV-2.4 eV, and thus, after the light enters the transparent substrate 100, the first solar cell unit 104 may absorb the incident light with short wavelength, such that the yellowing problem of the spacer 112 caused by absorbing UV light may be prevented, in which the spacer 112 includes ethylene vinyl acetate copolymer (EVA), PVB, silica gel, and the like, for example. Moreover, power generation may be conducted to the external circuit (not shown) by the first electrode 106 and the second electrode 108. The first electrode 106 and the second electrode 108 are independently transparent conductive oxide (TCO), metal, conductive polymer, organic-inorganic hybrid, or polar material, for example. In one embodiment, the electrodes can be pervious to the infrared light with long wavelength. The transparent conducting oxides may be indium tin oxides (ITO), zinc oxides (ZnO), tin oxides (SnO₂), gallium-doped zinc oxides (GZO), aluminum-doped zinc oxides (AZO), or co-doped tin oxides (LFTO), for example. The metal may be molybdenum (Mo), gold (Au), silver (Ag), aluminum (Al), copper (Cu), or nickel (Ni), for example. The conducive polymer may be poly(3,4-ethylenedioxythiophene) (PEDOT), poly(styrenesulfonate) (PSS), PEDOT:PSS, polyphenylene sulfide (PPS), polypyrrole (PPy), polythiophene (PT), or polyaniline/polystyrene (PANDB/PS), for example. The organic-inorganic hybrid may be poly(propylene glycol) tolylene 2,4-diisocyanate terminated (PPGTDI) (i.e. a polymer of 1,3-diisocyanatomethylbenzene and α-hydro-ω-hydroxy-poly [oxy(methyl-1,2-ethanediyl)]), poly(propylene glycol)-block-poly(ethylene glycol)-block-poly(propylene glycol) bis(2-aminopropyl ether) (ED2000) (i.e. a polymer of 1,2-epoxypropane, polyethylene glycol and bis(2-aminopropyl ether)), or 3-isocyanatepropyltriethoxysilane (ICPTES), for example. The polar material may be magnesium diboride in a molten state, or a carbon nanotube film (CNT), or the like. If the first electrode 106 and the second electrode 108 are opaque material, it may be made into wires or patterned conductive layers.

As for the crystalline silicon solar cell 102, it includes a top electrode 114, a bottom electrode 116, and a crystalline silicon absorbent layer 118 between the top electrode 114 and the bottom electrode 116. Also, the top electrode 114 is close to the spacer 112 while the bottom electrode 116 is away from the spacer 112. The top electrode 114 and the bottom electrode 116 are independently transparent conductive oxide, metal, conductive polymer, organic-inorganic hybrid, or polar material. Furthermore, when the top electrode 114 and the bottom electrode 116 are opaque material, at least the top electrode 114 on the surface that light enters may be made into a wire or a patterned conductive layer, and/or the top electrode 114 and the bottom electrode 116 may have openings (not shown) in positions relative to the first electrode 106 and the second electrode 108 for light penetration.

According to the first embodiment, due to the existence of the first solar cell unit 104, yellowing of the encapsulation material inside the PV module may be avoided. Also, since the light with short wavelength to the crystalline silicon solar cell 102 may be reduced, the effect of indirectly-heating crystalline silicon from thermal radiation may be reduced. In addition, because the first solar cell unit 104 absorbing the light with short wavelength also has the function of power generation, the utilization rate of the spectrum may be enhanced. Thus, the total power generation may be increased. Besides, since single transparent substrate 100 is utilized in the PV module in the embodiment, a weight of the module is less than other stacked PV modules, whereby broadening application, facilitating transporting, and reducing the cost.

FIG. 2 is a schematic cross-sectional view of a PV module in accordance with a second embodiment of the disclosure, wherein the component symbols the same as in FIG. 1 are used to represent the same or similar components.

Referring to FIG. 2, the difference between the PV modules in the second embodiment and FIG. 1 is a structure of the first solar cell unit 200. In one embodiment, the first solar cell unit 200 includes a first electrode 202, a second electrode 204, and a I-III-VI semiconductor layer 206 located between the first electrode 202 and the second electrode 204. The selection for the material of the I-III-VI semiconductor layer 206 may refer to the first embodiment, so it will not be described again. The first electrode 202 and the second electrode 204 are respectively located on opposite edges 206a and 206b of the I-III-VI semiconductor layer 206, and both the first electrode 202 and the second electrode 204 are in contact with the transparent substrate 100 and the spacer 112. Since the light is not blocked as such configuration of the first electrode 202 and the second electrode 204, they may be metal with low resistance and high conductivity selected from TCO, metal, conductive polymer, organic-inorganic hybrid, or polar material. Besides, the I-III-VI semiconductor layer 206 is filled between the first electrode 202 and the second electrode 204 as shown in FIG. 2. Alternatively, the I-III-VI semiconductor layer 206 may be adhered to the transparent substrate 100 while not in contact with the spacer 112 for reducing a thickness of the I-III-VI semiconductor layer 206 such that a balance may be made between the performances of short-wavelength light absorption and long-wavelength light transmission.

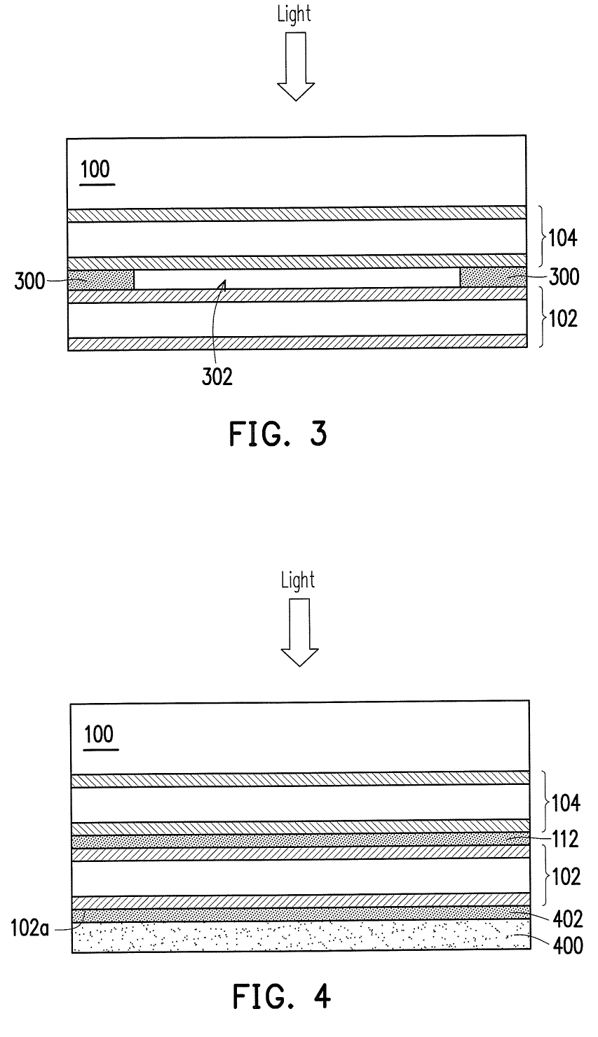

FIG. 3 is a schematic cross-sectional view of a PV module in accordance with a third embodiment of the disclosure, wherein the component symbols the same as in FIG. 1 are used to represent the same or similar components.

Referring to FIG. 3, the difference between the PV modules in the third embodiment and FIG. 1 is a structure of the spacer 300. In one embodiment, the spacer 300 partially covers the crystalline silicon solar cell 102, so a space 302 is formed between the crystalline silicon solar cell 102 and the first solar cell unit 104, wherein the environment within the space 302 includes air or inert gas. Because of most regions between the crystalline silicon solar cell 102 and the first solar cell unit 104 without the spacer, the light is favorable to be transmitted while not be absorbed by other structures.

FIG. 4 is a schematic cross-sectional view of a PV module in accordance with a fourth embodiment of the disclosure, wherein the component symbols the same as in FIG. 1 are used to represent the same or similar components.

Referring to FIG. 4, the difference between the PV modules in the fourth embodiment and FIG. 1 is the addition of a back plate 400 and a polymer insulator 402. The back plate 400 is attached on the light-emitting surface 102a of the crystalline silicon solar cell 102 by the polymer insulator 402. The back plate 400 may be Tedlar®, for example, and the polymer insulator 402 may be, such as EVA, PVB, or silica gel.

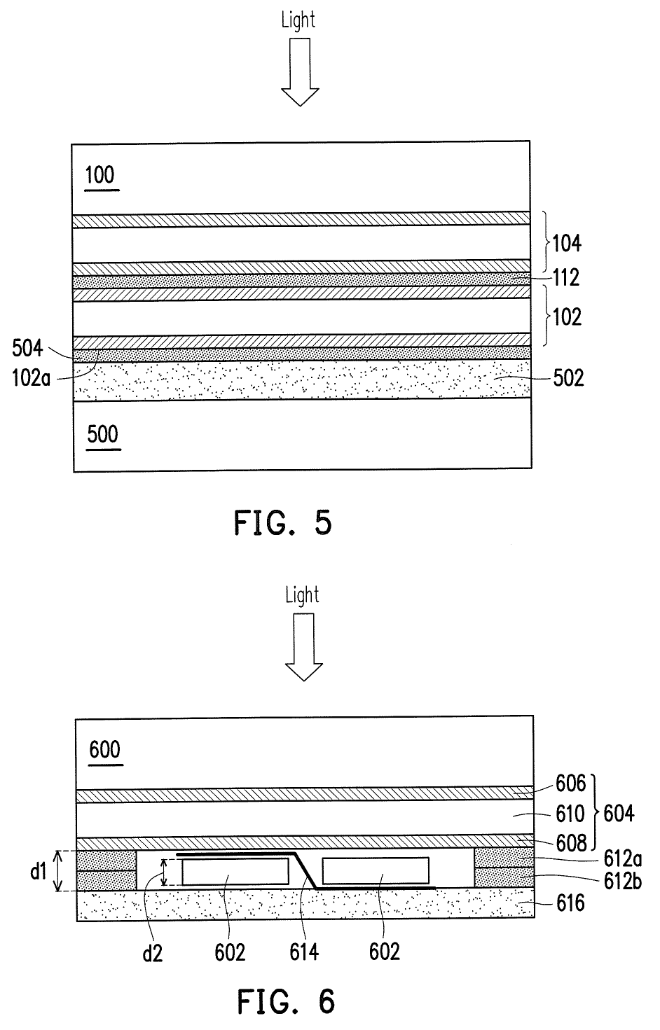

FIG. 5 is a schematic cross-sectional view of a PV module in accordance with a fifth embodiment of the disclosure, wherein the component symbols the same as in FIG. 1 are used to represent the same or similar components.

Referring to FIG. 5, the difference between the PV modules in the fifth embodiment and FIG. 1 is the addition of an additional substrate 500, a second solar cell unit 502, and an encapsulation layer 504. The additional substrate 500 is on the light-emitting surface 102a of the crystalline silicon solar cell 102. The second solar cell unit 502 is located between the additional substrate 500 and the crystalline silicon solar cell 102, and is bonded to the crystalline silicon solar cell 102 by the encapsulation layer 504. If a band gap of an absorbent layer of the second solar cell unit 502 is less than the band gap of crystalline silicon, it may be used to absorb the light not be absorbed by the crystalline silicon solar cell 102, and the power generation may be conducted to outside by electrodes (not shown) therein.

FIG. 6 is a schematic cross-sectional view of a PV module in accordance with a sixth embodiment of the disclosure.

Referring to FIG. 6, a PV module in the sixth embodiment includes a transparent substrate 600, a crystalline silicon solar cell 602, a solar cell unit 604 (including a first electrode 606, a second electrode 608, and a I-III-VI semiconductor layer 610), and spacers 612a and 612b. Each component in the embodiment may refer to the above-mentioned embodiments, so it will not be repeated again.

Since the crystalline silicon solar cells 602 are series connected by PV ribbons 614 in the embodiment, and the spacer 612a and the spacer 612b are disposed around the crystalline silicon solar cells 602, a thickness d1 of the spacer 612a and the spacer 612b is greater than a thickness d2 of the crystalline silicon solar cell 602. Also, an area of the transparent substrate 600 is greater than an area of the crystalline silicon solar cells 602. In the figure, the crystalline silicon solar cells 602 are separated slightly from the PV ribbons 614, but the PV ribbons 614 are directly soldered on electrodes (not shown) of the crystalline silicon solar cells 602 in actuality. A back plate 616 is provided to dispose the crystalline silicon solar cells 602 thereon. Therefore, the crystalline silicon solar cells 602 are not in contact with or electrically connected to the second electrode 608 of the solar cell unit 604. Besides, since the solar cell unit 604 may be coated with the spacer 612a, and the back plate 616 may be coated with the spacer 612b in the manufacturing process, and then an encapsulation is performed by combination of the spacer 612a and the spacer 612b. Accordingly, the spacer 612a and the spacer 612b are two layers as shown in FIG. 6. However, the disclosure is not limited thereto.

In summary, since the solar cell unit is disposed between the transparent substrate and the crystalline silicon solar cell to absorb the light with short wavelength (e.g. UV light) of the disclosure, yellowing of the encapsulation material inside the PV module may be avoided. Also, because crystalline silicon with short wavelength is reduced, the effect of indirectly-heating crystalline silicon from thermal radiation may be reduced. Since the encapsulation material above-mentioned is difficult to yellowing, the module life is increased and the incident light is not blocked. Besides, the solar cell unit absorbing the light with short wavelength also has an electric energy generating function, so additional utility is increased while the levelized cost of electricity (LCOE) is reduced. Thus, the utility of the solar irradiation spectrum may be enhanced, and the total electric energy generation may be increased. In addition, since single transparent substrate (e.g. glass) may be used in the PV module of the disclosure, the weight of the module is decreased along with reduction of pieces of glass, whereby broadening application, facilitating transporting, and reducing the cost. The above effects may cause the reduction of the levelized cost of electricity (LCOE).

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

1. A PV module, comprising:
a transparent substrate;
a crystalline silicon solar cell, comprising a top electrode, a bottom electrode, and a crystalline silicon absorbent layer between the top electrode and the bottom electrode;
a first solar cell unit located between the transparent substrate and the crystalline silicon solar cell, and the first solar cell unit comprises a first electrode, a second electrode, and a I-III-VI semiconductor layer between the first electrode and the second electrode, wherein the I-III-VI semiconductor layer comprises at least gallium (Ga) and sulfur (S) and an energy gap thereof is more than that of crystalline silicon; and
a spacer, is configured to separate the crystalline silicon solar cell and the first solar cell unit,
wherein the first electrode, the second electrode, the top electrode, and the bottom electrode have a plurality of openings in relative positions.

2. The PV module according to claim 1, wherein the first solar cell unit absorbs a light with a wavelength of 800 nm or less.

3. The PV module according to claim 1, wherein the transparent substrate comprises glass or plastic.

4. The PV module according to claim 1, wherein a material of the I-III-VI semiconductor layer comprises copper (indium, gallium) disulfide (Cu(In,Ga)S₂), copper gallium disulfide (CuGaS₂), (copper, silver) (indium, gallium) disulfide ((Cu,Ag)(In,Ga)S₂), (copper, silver) gallium disulfide ((Cu,Ag)GaS₂), copper (indium, gallium) oxy-sulfide (Cu(In,Ga)(O,S)₂), copper gallium oxy-sulfide (CuGa(O,S)₂), (copper, silver) (indium, gallium) oxy-sulfide ((Cu,Ag)(In,Ga)(O,S)₂), or copper (indium, gallium) (selenium, sulfide) (Cu(In,Ga)(Se,S)₂).

5. The PV module according to claim 1, wherein the first electrode and the second electrode independently comprise transparent conductive oxide, metal, conductive polymer, organic-inorganic hybrid, or polar material.

6. The PV module according to claim 1, wherein the first electrode and the second electrode are respectively located on both surfaces of the I-III-VI semiconductor layer in a thickness direction.

7. The PV module according to claim 1, wherein the first electrode and the second electrode are respectively located on opposite edges of the I-III-VI semiconductor layer, and both the first electrode and the second electrode are in contact with the transparent substrate and the spacer.

8. The PV module according to claim 1, wherein the top electrode is close to the spacer while the bottom electrode is away from the spacer.

9. The PV module according to claim 1, wherein the top electrode and the bottom electrode independently comprise transparent conductive oxide, metal, conductive polymer, organic-inorganic hybrid, or polar material.

10. (canceled)

11. The PV module according to claim 1, wherein the crystalline silicon solar cell is completely covered with the spacer.

12. The PV module according to claim 1, wherein the crystalline silicon solar cell is partially covered with the spacer so that a space is formed between the crystalline silicon solar cell and the first solar cell unit.

13. The PV module according to claim 12, wherein the environment within the space is air or inert gas.

14. The PV module according to claim 1, further comprising a back plate and a polymer insulator, wherein the back plate is bonded to a light-emitting surface of the crystalline silicon solar cell through the polymer insulator.

15. The PV module according to claim 1, further comprising:
an additional substrate located on a light-emitting surface of the crystalline silicon solar cell;
a second solar cell unit located between the additional substrate and the crystalline silicon solar cell; and
an encapsulation layer located between the crystalline silicon solar cell and the second solar cell unit.

16. The PV module according to claim 15, wherein an energy gap of an absorbent layer of the second solar cell unit is less than the energy gap of crystalline silicon.

17. The PV module according to claim 1, wherein the spacer is disposed around the crystalline silicon solar cell and a thickness thereof is more than that of the crystalline silicon solar cell.

18. The PV module according to claim 1, wherein an area of the transparent substrate is greater than an area of the crystalline silicon solar cell.
